(19) United States
(12) Patent Application Publication
(10) Pub. No.: US 2021/0399529 A1
(43) Pub. Date: Dec. 23, 2021

(54) SEMICONDUCTOR LASER

(71) Applicant: OSRAM Opto Semiconductors GmbH, Regensburg (DE)

(72) Inventors: Jörg Erich SORG, Regensburg (DE); Jan MARFELD, Regensburg (DE); Stefan MORGOTT, Pentling (DE)

(21) Appl. No.: 17/291,541

(22) PCT Filed: Nov. 5, 2019
(86) PCT No.: PCT/EP2019/080243

§ 371 Date: May 5, 2021

(30) Foreign Application Priority Data
Nov. 15, 2018 (DE) 10 2018 128 751.8

(51) Int. Cl. H01S 5/40; H01S 5/026; H01S 5/028

(52) U.S. Cl. CPC H01S 5/4031; H01S 5/0287; H01S 5/0262

(57) ABSTRACT

A semiconductor laser includes an edge-emitting laser diode, which has an active zone for generating laser radiation and a facet having a radiation exit region, and at least one photodiode. The facet is arranged on a main emission side of the laser diode. The photodiode is arranged in such a way that at least part of the laser radiation exiting at the facet reaches the photodiode. The laser diode and the photodiode are not connected to each other in a non-destructively detachable manner, and a non-destructively detachable connection is formed with a joining partner

A semiconductor laser is specified.

It is an object of the present disclosure to specify a semiconductor laser that can be operated particularly safely.

According to at least one embodiment of the semiconductor laser, the semiconductor laser comprises an edge-emitting laser diode, which has an active zone for generating laser radiation and a facet having a radiation exit region. The semiconductor laser has a main extension plane. The edge-emitting laser diode is configured to emit laser radiation during operation in a direction that is, for example, at least partially parallel to the main extension plane of the semiconductor laser. The active zone has a main extension plane which is parallel to the main extension plane of the semiconductor laser. Thus, the laser diode is in particular not a surface emitter.

The laser diode may comprise various semiconductor materials, for example based on a III-V semiconductor material system.

The facet is oriented transverse, preferably perpendicular to the main extension plane of the active zone. Further, the facet is oriented transverse, preferably perpendicular to a main propagation direction of the laser radiation emitted during operation. In the radiation exit region, the laser radiation generated during operation exits the laser diode. The radiation exit region is in particular a partial region of the facet and thus limited to the facet.

According to at least one embodiment of the semiconductor laser, the semiconductor laser comprises at least one photodiode. The photodiode is configured to detect electromagnetic radiation. The photodiode may be a detector. The photodiode may have a radiation entrance side. The photodiode may comprise various semiconductor materials, for example based on a III-V semiconductor material system.

According to at least one embodiment of the semiconductor laser, the facet is arranged on a main emission side of the laser diode. A majority of the laser radiation emitted by the laser diode during operation exits the laser diode on the main emission side. This may mean that at least 90% of the laser radiation emitted by the laser diode during operation exits the laser diode on the main emission side. The proportion of the laser radiation emitted by the laser diode during operation which exits the laser diode on the main emission side is greater than the proportion which exits the laser diode at other locations.

According to at least one embodiment of the semiconductor laser, the photodiode is arranged in such a way that at least part of the laser radiation exiting at the facet reaches the photodiode. Part of the laser radiation exiting from the facet may reach the photodiode directly or indirectly. This means that part of the laser radiation exiting the facet may be deflected or reflected to reach the photodiode. Alternatively, at least part of the laser radiation exiting the facet may directly impinge on the photodiode. The photodiode can be arranged on a side of the laser diode facing the facet.

The photodiode can be designed to detect the laser radiation emitted by the laser diode. This can mean that the absorption of the photodiode has a maximum in a wavelength range in which the laser radiation emitted by the laser diode has a maximum in intensity.

According to at least one embodiment of the semiconductor laser, the laser diode and the photodiode are not connected to each other in a non-destructively detachable manner. This may mean that the laser diode and the photodiode are connected to each other in such a way that the semiconductor laser, in particular at least one component of the semiconductor laser, is at least partially destroyed when the connection is disconnected. It is further possible that the laser diode and/or the photodiode are at least partially destroyed when the connection is disconnected. Thus, the laser diode and the photodiode may be inseparably connected. In particular, the laser diode and the photodiode may also be indirectly connected to each other. This can mean that the laser diode and the photodiode are not in direct contact, but are connected to each other via a connection element.

A not non-destructively detachable connection can be made, for example, by an Au/Sn solder joint of the components. Furthermore, a not non-destructively detachable connection can be created by anodic bonding, for example of the glass and silicon joining partners. Furthermore, joining the components using reactive solder systems, in which intermetallic compounds are formed by reaction of metals, leads to a not non-destructively detachable connection. For example, the solder systems In/Sn, Sn/Ni and/or Cu/Sn are used for this purpose. Furthermore, a not non-destructively detachable connection can be created by Au/Au compression bonding. For example, one of the mentioned connections can be directly created between the laser diode and the photodiode. Further, it is possible that one of said connections is created between the laser diode and the connection element and/or one of said connections is created between the photodiode and the connection element.

According to at least one embodiment of the semiconductor laser, the semiconductor laser comprises an edge-emitting laser diode, which has an active zone for generating laser radiation and a facet having a radiation exit region, and at least one photodiode, wherein the facet is arranged on a main emission side of the laser diode, the photodiode is arranged in such a way that at least part of the laser radiation exiting at the facet reaches the photodiode, and the laser diode and the photodiode are not connected to each other in a non-destructively detachable manner.

For semiconductor lasers in applications that are used in close proximity to the human eye, it is particularly important to monitor the intensity of the laser radiation emitted by the semiconductor laser. To protect the human eye, the intensity of the laser radiation emitted by the semiconductor laser should not exceed a certain maximum intensity. Therefore, a photodiode is used to measure the intensity of the laser radiation emitted by the laser diode. The photodiode is designed to detect at least part of the electromagnetic laser radiation emitted by the laser diode during operation. This means that the photodiode may be designed to determine the intensity of the detected laser radiation. Thus, changes in the intensity of the laser radiation emitted by the laser diode during operation can be detected. Furthermore, it can be detected whether the laser radiation emitted by the laser diode is less than the maximum intensity.

Advantageously, the photodiode is arranged in such a way that at least part of the laser radiation exiting at the facet reaches the photodiode. This means that the photodiode detects laser radiation exiting from the laser diode on the main emission side. The laser radiation exiting on the main emission side is usually coupled out of the semiconductor laser and used in the respective application. Since the photodiode detects at least part of the laser radiation exiting on the main emission side, the laser radiation reaching the human eye is monitored by the photodiode. This allows for increased safety in monitoring the laser radiation emitted from the semiconductor laser, since the intensity of the laser radiation used in an application is measured. In contrast, measuring the intensity of laser radiation exiting on other sides of the laser diode results in greater inaccuracy in determining the intensity of laser radiation exiting from the semiconductor laser. Accurate determination of the intensity of the laser radiation emitted from the semiconductor laser increases safety when using the semiconductor laser.

According to at least one embodiment of the semiconductor laser, the photodiode and the laser diode are arranged on a common carrier. The carrier may be a submount or the carrier may comprise a mounting element. The carrier may be a three-dimensional body and may, for example, be in the form of a cylinder, a disk, or a cuboid. The carrier may have a main extension plane. The main extension plane of the carrier is, for example, parallel to a surface, for example a top surface, of the carrier. It is possible that the carrier comprises a driver that can be used to drive the laser diode. Alternatively, it is possible that the carrier is an electronically passive component and serves only as a mounting plane. The carrier may comprise a semiconductor material.

The laser diode can be arranged on the top surface of the carrier. The laser diode can be connected to the carrier via electrical contacts so that the laser diode can be controlled via the carrier. For example, the laser diode has electrical contacts on the side facing the top surface of the carrier, which are electrically connected to the carrier. Alternatively, it is possible that the laser diode is electrically connected to the carrier via bonding wires. The laser diode can be mechanically attached to the carrier on the top surface.

The photodiode can also be arranged on the top surface of the carrier. The photodiode can be connected to the carrier via electrical contacts so that the photodiode can be controlled via the carrier. For example, the photodiode has electrical contacts on the side facing the top surface of the carrier, which are electrically connected to the carrier. Alternatively, it is possible that the photodiode is electrically connected to the carrier via bonding wires. The photodiode may be mechanically attached to the carrier on the cover surface.

The carrier can be a connecting element via which the laser diode and the photodiode are connected to each other in a not non-destructively detachable manner. Thus the semiconductor laser has an increased stability. In addition, the semiconductor laser can have a compact design.

According to at least one embodiment of the semiconductor laser, the photodiode is attached to a cover of the semiconductor laser. The laser diode and the photodiode may be arranged in a cavity of the semiconductor laser. The cover may be arranged such that the cavity is arranged between the cover and the carrier. The cover may have a main extension plane that is parallel to the main extension plane of the carrier. At least in places, the cover is transmissive to the laser radiation emitted by the laser diode. This means that the cover may be transparent, at least in places, to the laser radiation emitted by the laser diode. The cover may be a substrate for the photodiode. Semiconductor layers of the photodiode may be grown on the substrate. It is further possible that the photodiode is attached to the cover. The cover comprises, for example, sapphire or SiC or consists of one of these materials.

The cover can have a radiation-transmissive region through which the laser radiation emitted by the laser diode exits the semiconductor laser. The photodiode can be arranged at least in places in the radiation-transmissive region. In this case, the photodiode is arranged on a side of the cover facing the laser diode. Furthermore, the photodiode is at least in places transmissive to the laser radiation emitted by the laser diode. Advantageously, the laser radiation leaving the semiconductor laser is thus detected by the photodiode. Thus, for example, for applications in the vicinity of the human eye, it can be measured directly whether the laser radiation emitted by the semiconductor laser is below the maximum intensity.

It is further possible that the photodiode is not arranged in the radiation-transmissive region. In this case, the photodiode is arranged next to the radiation-transmissive region. This means that the photodiode is not necessarily transmissive to the laser radiation emitted by the laser diode. Also in this case, part of the laser radiation emitted from the semiconductor laser can advantageously be detected by the photodiode.

According to at least one embodiment of the semiconductor laser, an optical element is arranged between the laser diode and the photodiode, the optical element being configured to direct part of the laser radiation emitted by the laser diode towards the photodiode. The optical element may have a main surface. In this case, the optical element is arranged in such a way that laser radiation emerging from the laser diode at the facet impinges on the main surface. At least part of the incident laser radiation can be deflected at the main surface. Further, it is possible that at least part of the laser radiation incident on the main surface enters the optical element. The photodiode can be arranged on a side of the optical element that is not the side on which the main surface is arranged. On the side of the optical element facing the photodiode, at least part of the laser radiation may exit the optical element and impinge on the photodiode. An optical filter may be arranged between the optical element and the photodiode. The optical element may comprise glass.

By using the optical element, part of the laser radiation emerging from the laser diode on the main emission side can be detected by the photodiode.

According to at least one embodiment of the semiconductor laser, the optical element is arranged on a carrier for the photodiode and the laser diode. This means that the photodiode and the laser diode are arranged on a common carrier and that the optical element is also arranged on this carrier. The optical element may be arranged directly on the carrier. The optical element may be fixed on the carrier. It is further possible that the optical element is arranged on the photodiode. Since the optical element is also arranged on the carrier, the stability of the semiconductor laser is increased.

According to at least one embodiment of the semiconductor laser, the optical element is partially transmissive to the laser radiation emitted by the laser diode and partially reflective to the laser radiation emitted by the laser diode. A partially reflective layer may be arranged on the main surface of the optical element, said partially reflective layer being partially transmissive to the laser radiation emitted from the laser diode and partially reflective to the laser radiation emitted from the laser diode. The reflectivity of the partially reflective layer for the incident laser radiation is, for example, at least 70% or at least 90%. The transmissivity of the partially reflective layer for the incident laser radiation may be at least 1% or at least 5%. The partially reflective layer comprises, for example, a metal or a dielectric material. Thus, the optical element is configured to direct part of the laser radiation emitted by the laser diode towards the photodiode.

According to at least one embodiment of the semiconductor laser, the optical element is configured to change the main propagation direction of at least part of the laser radiation emitted by the laser diode. The main propagation direction of the laser radiation emitted by the laser diode at the facet is parallel to the main extension plane of the carrier. The main propagation direction may be the beam direction of the laser radiation. The laser radiation emitted from the semiconductor laser has a main propagation direction which is different from the main propagation direction of the laser radiation emitted by the laser diode. By impinging on the optical element, the main propagation direction of the laser radiation is changed. For example, the main propagation direction of the laser radiation emitted from the semiconductor laser is transverse or perpendicular to the main extension plane of the carrier. The main propagation direction of the laser radiation emerging from the semiconductor laser can run in a direction away from the carrier.

The optical element further offers the possibility to deflect the laser radiation emerging from the laser diode or to reduce the beam width of the emerging laser radiation. Thus, the semiconductor laser can be a surface emitter.

Further, it is possible that the optical element does not change the main propagation direction of the laser radiation emitted by the laser diode. In this case, the laser radiation can be coupled out laterally from the semiconductor laser.

According to at least one embodiment of the semiconductor laser, the photodiode is at least locally transmissive to the laser radiation emitted by the laser diode. This may mean that the photodiode is at least locally transparent to the laser radiation emitted by the laser diode. The photodiode may have a transmissivity of at least 80% or at least 90% for the laser radiation emitted by the laser diode. The photodiode may be arranged between the optical element and the laser diode. Thus, all or most of the laser radiation emitted from the laser diode may impinge on the photodiode.

This allows accurate determination of the intensity of the laser radiation emerging from the laser diode on the main emission side. Therefore, the semiconductor laser can be operated safely.

According to at least one embodiment of the semiconductor laser, the semiconductor laser has a cover on a radiation exit side, which is partially transmissive to the laser radiation emitted by the laser diode and partially reflective to the laser radiation emitted by the laser diode. A cavity of the semiconductor laser may be arranged between the cover and the carrier. The cover may cover the laser diode and the photodiode. Furthermore, the semiconductor laser may be hermetically sealed with the cover on the radiation exit side. That is, there is no significant exchange of substances such as oxygen or water vapor between the cavity and the environment of the semiconductor laser. Hermetically sealed means, for example, that a leakage rate is at most 5×10⁻⁹ Pa m/s, especially at room temperature. The radiation exit side may be located on a side of the laser diode facing away from the carrier. The cover may have a main extension plane which is parallel to the main extension plane of the carrier. The cover may comprise a material that is transmissive to the laser radiation emitted by the laser diode. The material may be sapphire, SiC, glass, plastic, or a silicone-based material.

On the side facing the carrier, a partially reflective layer can be applied to this material, said partially reflective layer being partially transmissive to the laser radiation emitted by the laser diode and partially reflective to the laser radiation emitted by the laser diode. The partially reflective layer comprises, for example, a metal or a dielectric material. At the partially reflective layer, part of the laser radiation emitted by the laser diode can be reflected and directed towards the photodiode. This means that the photodiode detects part of the laser radiation emitted from the laser diode on the main emission side. Thus, the semiconductor laser can be operated safely.

According to at least one embodiment of the semiconductor laser, the laser diode and the photodiode are arranged in a common housing. The housing may be formed by the cover and side walls. The side walls may completely surround the laser diode and the photodiode in lateral directions, the lateral directions being parallel to the main extension plane of the carrier. The side walls may be arranged on the carrier. The laser diode and the photodiode may be arranged in a hermetically sealed cavity bounded by the cover, the side walls and the carrier. Thus, the laser diode and the photodiode are stably and compactly arranged in the semiconductor laser.

According to at least one embodiment of the semiconductor laser, the photodiode is a component of a carrier for the laser diode. Thus, the photodiode may be an integral part of the carrier. The laser diode is arranged on the carrier. The carrier may include a driver such that the photodiode and the laser diode may be controlled via the carrier. The carrier may comprise a semiconductor material such as Si, Ge, or SiC. The photodiode may be arranged on the main emission side of the laser diode in the carrier. Thus, part of the laser radiation emitted from the facet can directly impinge on the photodiode. This means that the intensity of the emitted laser radiation can be determined with a high degree of accuracy. This increases safety when using the semiconductor laser.

According to at least one embodiment of the semiconductor laser, a carrier for the laser diode has a recess in which the photodiode is arranged. The laser diode is arranged on the carrier. The photodiode is arranged in the recess of the carrier. For example, the recess of the carrier is located in the area of the optical element. This means that the recess with the photodiode is arranged between the optical element and the carrier. Thus, the semiconductor laser has an overall compact structure. In addition, the laser diode and the photodiode are stably connected to each other.

According to at least one embodiment of the semiconductor laser, the main extension plane of the photodiode is transverse or perpendicular to the main extension plane of the facet. In this case, the photodiode may be attached to the carrier or to the cover. The main radiation direction of the laser diode is parallel to the main extension plane of the photodiode. This means that at least part of the laser radiation emitted by the laser diode is deflected so that it impinges on the photodiode at a different angle. Since the main extension plane of the photodiode is transverse or perpendicular to the main extension plane of the facet, the photodiode can be stably arranged in the semiconductor laser.

According to at least one embodiment of the semiconductor laser, the main extension plane of the photodiode is parallel to the main extension plane of the facet. The photodiode may be attached to the carrier. For example, the photodiode is arranged such that laser radiation emerging from the facet directly impinges on the photodiode. In this case, the photodiode is at least partially transmissive to the laser radiation emitted by the laser diode. It is further possible that the photodiode is arranged adjacent to the optical element. In this case, the photodiode may be arranged on a side of the optical element facing away from the main side. Advantageously, no deflection of the laser radiation for detection by the photodiode is necessary if the main extension plane of the photodiode is parallel to the main extension plane of the facet.

According to at least one embodiment of the semiconductor laser, an optical filter is arranged on the photodiode at least in places. The optical filter may be transmissive to electromagnetic radiation in a certain wavelength range and impermeable to electromagnetic radiation outside that certain wavelength range. The wavelength of the laser radiation emitted by the laser diode may be within this wavelength range. By using the optical filter, the accuracy of the measurement of the intensity of the laser radiation by the photodiode can be increased. For example, stray light cannot pass through the optical filter to the photodiode.

According to at least one embodiment of the semiconductor laser, a partially reflective layer is arranged on the photodiode, said partially reflective layer being configured to direct part of the laser radiation emitted by the laser diode in the direction of the photodiode. The partially reflective layer is partially transmissive to the laser radiation emitted by the laser diode and partially reflective to the laser radiation emitted by the laser diode. Thus, part of the laser radiation incident on the photodiode is reflected at the partially reflective layer and another part of the incident laser radiation passes through the partially reflective layer to the photodiode. The partially reflective layer comprises, for example, a metal or a dielectric material. Thus, the photodiode can detect part of the laser radiation emitted on the main emission side. By accurately determining the intensity of the laser radiation emerging from the laser diode, the semiconductor laser can be operated safely.

According to at least one embodiment of the semiconductor laser, a surface of the photodiode is uneven. The surface may be the surface of the photodiode at which electromagnetic radiation to be detected can enter the photodiode. The surface of the photodiode which is uneven may face the laser diode. Further, it is possible that the surface of the photodiode which is uneven is a surface facing away from the carrier. That a surface of the photodiode is uneven may mean that the surface is curved. Further, it is possible that the surface has a curved shape or does not extend completely parallel to a plane. The surface of the photodiode may have a concave shape. This may mean that the surface is curved towards the center of the photodiode. On the surface of the photodiode which is uneven, the partially reflective layer may be arranged. Laser radiation emitted by the laser diode can be shaped and/or deflected at the uneven surface of the photodiode. Thus, advantageously, no additional optical element is required.

In the following, the semiconductor laser described herein is explained in more detail in connection with exemplary embodiments and the associated figures.

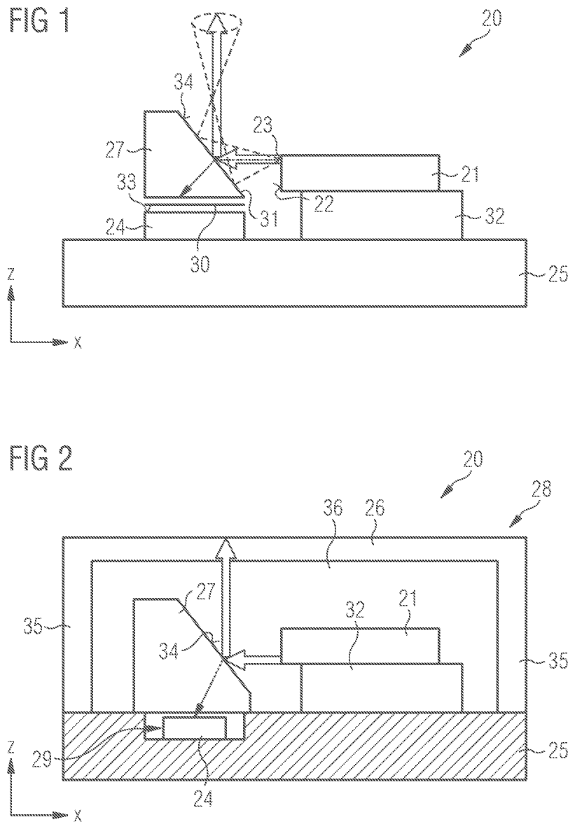

FIG. 1 shows a schematic cross-section through a semiconductor laser according to an exemplary embodiment.

FIGS. 2, 3, 4, 5, 6, 7, 8, 9 and 10 show cross-sections through further exemplary embodiments of the semiconductor laser.

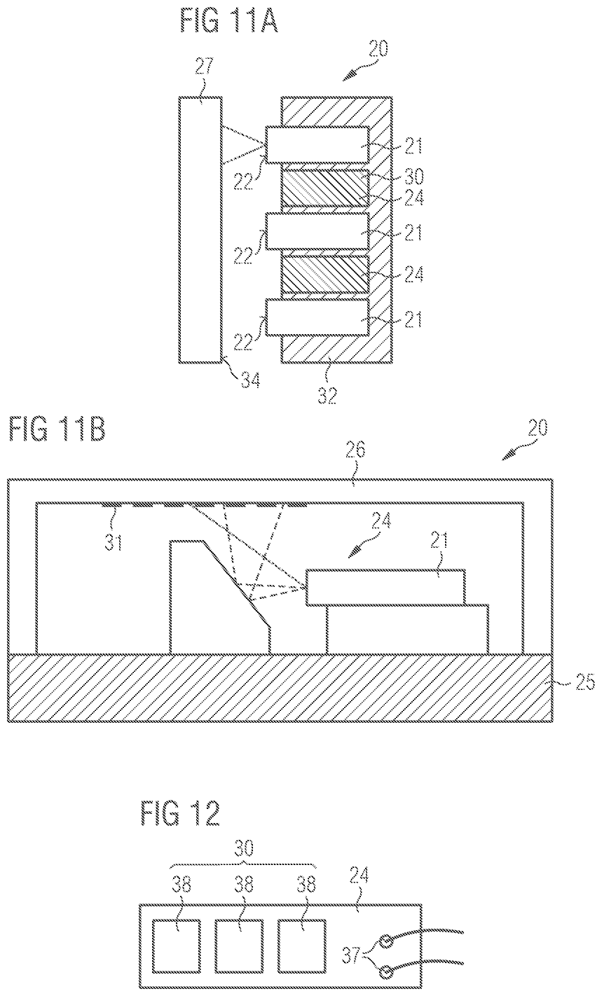

FIG. 11A shows a top view of a semiconductor laser according to another exemplary embodiment.

FIG. 11B shows a schematic cross-section through the semiconductor laser according to another exemplary embodiment.

FIG. 12 shows a top view of a photodiode according to an exemplary embodiment.

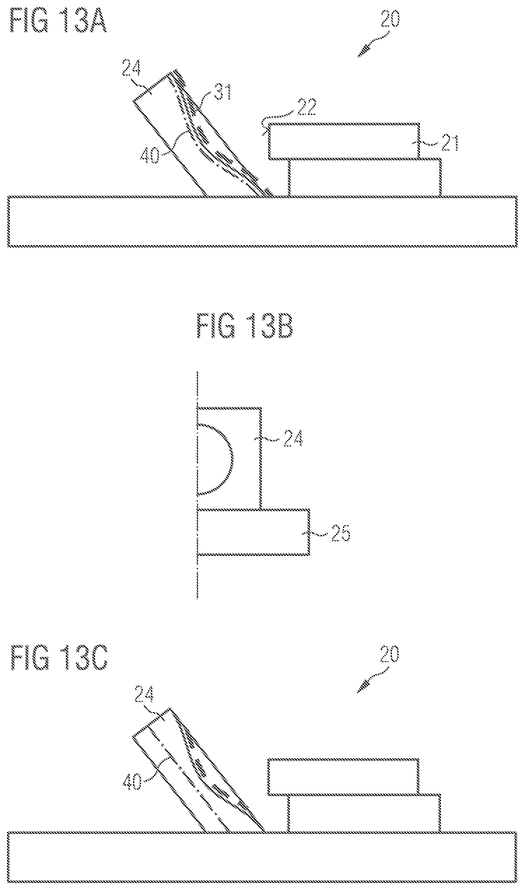

FIGS. 13A, 13B and 13C show further exemplary embodiments of the semiconductor laser.

Elements that are identical, similar or have the same effect are marked with the same reference signs in the figures. The figures and the proportions of the elements shown in the figures are not to be regarded as true to scale. Rather, individual elements may be shown exaggeratedly large for better representability and/or for better comprehensibility.

FIG. 1 shows a schematic cross-section through a semiconductor laser 20 according to an exemplary embodiment. The semiconductor laser 20 is shown without a housing 28. This means that the encapsulation of the semiconductor laser 20 is arbitrary. The semiconductor laser 20 comprises an edge-emitting laser diode 21. The laser diode 21 has an active region for generating a laser radiation and a facet 22 having a radiation exit region 23. In FIG. 1, the radiation exit region 23 is located in the upper region of the facet 22. However, it is also possible that the radiation exit region 23 is located in a different region of the facet 22.

The facet 22 is arranged on a main emission side of the laser diode 21. This means that the laser diode 21 is configured to emit laser radiation mainly on the main emission side during operation. The laser diode 21 is arranged on a connection carrier 32. The connection carrier 32 may be a so-called submount. The connection carrier 32 may comprise a semiconductor material, such as Si, SiC, Ge or GaN, or sapphire. The laser diode 21 is electrically conductively connected to the connection carrier 32. Thus, the laser diode 21 can be controlled via the connection carrier 32.

The connection carrier 32 with the laser diode 21 is arranged on a carrier 25. The connection carrier 32 may be a part of the carrier 25. The carrier 25 may include a driver that can be used to control the laser diode 21. Alternatively, the carrier 25 may be an electronically passive component and serve only as a mounting plane. The carrier 25 may comprise a semiconductor material, such as Si, SiC, Ge or GaN, or sapphire.

The semiconductor laser 20 further comprises a photodiode 24. The photodiode 24 is arranged on the carrier 25. The photodiode 24 is arranged at a distance from the laser diode 21. Since the photodiode 24 and the laser diode 21 are both arranged on the carrier 25, they are not connected to each other in a non-destructively detachable manner. The photodiode 24 has a main extension plane which is parallel to a main extension plane of the carrier 25. Furthermore, the main extension plane of the photodiode 24 is perpendicular to the main extension plane of the facet 22. Further, the photodiode 24 has a radiation entrance side 33. The photodiode 24 is configured to detect electromagnetic radiation incident on the radiation entrance side 33. The radiation entrance side 33 is arranged on the side of the photodiode 24 facing away from the carrier 25.

An optical filter 30 is optionally arranged on the photodiode 24 at the radiation entrance side 33. The filter 30 is transmissive to electromagnetic radiation in a certain wavelength range and impermeable or less transmissive to electromagnetic radiation outside that wavelength range.

In a vertical direction z, an optical element 27 is arranged above the photodiode 24 and the filter 30, the vertical direction z being perpendicular to the main extension plane of the carrier 25. Thus, the filter 30 is arranged between the optical element 27 and the photodiode 24 in the vertical direction z.

The optical element 27 has the shape of a cuboid with a beveled side surface. The optical element 27 is arranged adjacent to the laser diode 21 in a lateral direction x, the lateral direction x being parallel to the main extension plane of the carrier 25. The optical element 27 is spaced apart from the laser diode 21. Thus, the optical element 27 is arranged between the laser diode 21 and the photodiode 24. The beveled side surface of the optical element 27 is a main surface 34, and the main surface 34 faces the laser diode 21. In particular, the main surface 34 faces the facet 22.

The optical element 27 is configured to direct part of the laser radiation emitted by the laser diode 21 towards the photodiode 24. In FIG. 1, the laser radiation emerging from the laser diode 21 is shown with arrows. The main propagation direction of the laser radiation emerging at the facet 22 is parallel to the main extension plane of the carrier 25. The laser radiation emerging at the facet 22 impinges on the main surface 34 of the optical element 27. The optical element 27 is partially transmissive to the laser radiation emitted by the laser diode 21 and partially reflective to the laser radiation emitted by the laser diode 21. Thus, part of the laser radiation is reflected at the main surface 34 and deflected in the vertical direction z.

The laser radiation is reflected at the optical element 27 in a direction away from the carrier 25. Another part of the laser radiation enters the optical element 27 at the main surface 34. This laser radiation partially exits the optical element 27 again on the side facing the photodiode 24. Thus, part of the laser radiation exiting at the facet 22 reaches the photodiode 24 and can be detected there. This enables safe and reliable monitoring of the intensity of the laser radiation emerging from the laser diode 21.

The portion of the laser radiation entering the optical element 27 may be small compared to the portion of the laser radiation reflected from the optical element 27. The reflected laser radiation may exit the semiconductor laser 20 in the vertical direction z. Thus, the optical element 27 is configured to change the main propagation direction of a portion of the laser radiation emitted by the laser diode 21. The semiconductor laser 20 is a surface emitter.

To deflect part of the emitted laser radiation at the optical element 27, a partially reflective layer 31 is applied to the main surface 34. The partially reflective layer 31 may comprise a metal. The thickness of the partially reflective layer 31 is thin enough to allow part of the incident laser radiation to enter the optical element 27 through the partially reflective layer 31. The optical element 27 may comprise a transparent material, such as glass.

FIG. 2 shows a schematic cross-section through another exemplary embodiment of the semiconductor laser 20. The laser diode 21 and the photodiode 24 are arranged in a common housing 28. The housing 28 has a cover 26 and side walls 35.

The side walls 35 are arranged on the carrier 25 and completely surround the laser diode 21 and the photodiode 24 in lateral directions x. In the vertical direction z, the side walls 35 extend further than the optical element 27 and the laser diode 21. The cover 26 is arranged on the side walls 35. The cover 26 extends over the entire lateral extent of the carrier 25. Thus, a cavity 36 is formed between the cover 26, the side walls 35 and the carrier 25. The laser diode 21 and the photodiode 24 are arranged in the cavity 36. The cavity 36 may be hermetically sealed from the external environment.

The cover 26 is arranged on a radiation exit side of the semiconductor laser 20. This means that the laser radiation emitted by the semiconductor laser 20 exits the semiconductor laser 20 through the cover 26. Therefore, the cover 26 is at least locally transmissive to the laser radiation emitted by the laser diode 21. The laser radiation emerging from the facet 22 is shown with an arrow. At the main surface 34, part of the laser radiation is reflected in the direction of the cover 26, so that the reflected laser radiation exits the semiconductor laser 20 in the vertical direction z.

The carrier 25, on which the connection carrier 32 with the laser diode 21 is arranged, has a recess 29. The photodiode 24 is arranged in the recess 29. The optical element 27 is arranged on the carrier 25 and above the photodiode 24. Part of the laser radiation incident on the main surface 34 passes through the optical element 27 to the photodiode 24, where it can be detected. Since the photodiode 24 is arranged in the recess 29, the semiconductor laser 20 can have a compact shape.

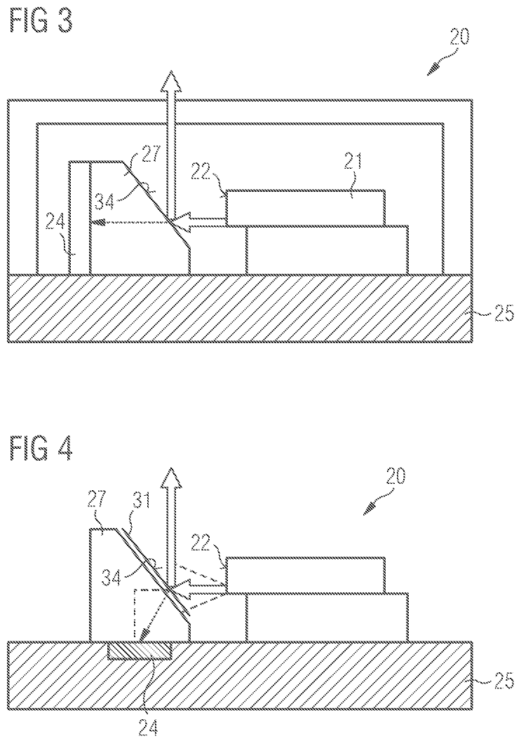

FIG. 3 shows a schematic cross-section through another exemplary embodiment of the semiconductor laser 20. Compared to the exemplary embodiment shown in FIG. 2, the carrier 25 does not have a recess 29. The photodiode 24 is arranged on the carrier 25. Here, the main extension plane of the photodiode 24 is parallel to the main extension plane of the facet 22. The optical element 27 is arranged between the laser diode 21 and the photodiode 24. The photodiode 24 is adjacent to a side surface of the optical element 27 which extends perpendicular to the main extension plane of the carrier 25. The photodiode 24 is adjacent to the side surface of the optical element 27 which faces away from the main surface 34. It is shown with an arrow that part of the laser radiation incident on the main surface 34 passes through the optical element 27 to the photodiode 24. In this case, the laser radiation incident on the photodiode 24 has the same main propagation direction as the laser radiation emerging from the facet 22. This exemplary embodiment of the semiconductor laser 20, too, can have a particularly compact design.

FIG. 4 shows a schematic cross-section through another exemplary embodiment of the semiconductor laser 20. In this exemplary embodiment, the encapsulation of the semiconductor laser 20 is arbitrary. Compared to the exemplary embodiment shown in FIG. 1, the photodiode 24 is arranged in the carrier 25. Thus, the photodiode 24 is an integral part of the carrier 25. The carrier 25 may comprise a semiconductor material such as Si, Ge, or SiC. As explained in connection with FIG. 1, part of the laser radiation emitted at the facet 22 passes through the optical element 27 to the photodiode 24. The partially reflective layer 31 is shown separately in this exemplary embodiment and completely covers the main surface 34.

FIG. 5 shows a schematic cross-section through another exemplary embodiment of the semiconductor laser 20. Compared to the exemplary embodiment shown in FIG. 1, the semiconductor laser 20 comprises no optical element 27. The photodiode 24 is arranged on the carrier 25 at a distance from the laser diode 21. The main extension plane of the photodiode 24 is transverse or oblique to the main extension plane of the facet 22. Furthermore, the main extension plane of the photodiode 24 is transverse or oblique to the main extension plane of the carrier 25.

A partially reflective layer 31 is arranged on the radiation entrance side 33 of the photodiode 24. The partially reflective layer 31 is partially transmissive to the laser radiation emitted by the laser diode 21 and partially reflective to the laser radiation emitted by the laser diode 21. This means that the partially reflective layer 31 is configured to direct part of the laser radiation emitted by the laser diode 21 towards the photodiode 24. Another part of the laser radiation emitted by the laser diode 21 is reflected by the partially reflective layer 31 and exits the semiconductor laser 20 in the vertical direction z. The partially reflective layer 31 may be constructed like a partially reflective layer 31 arranged on the optical element 27. Optionally, an optical filter 30 is also arranged on the radiation entrance side 33.

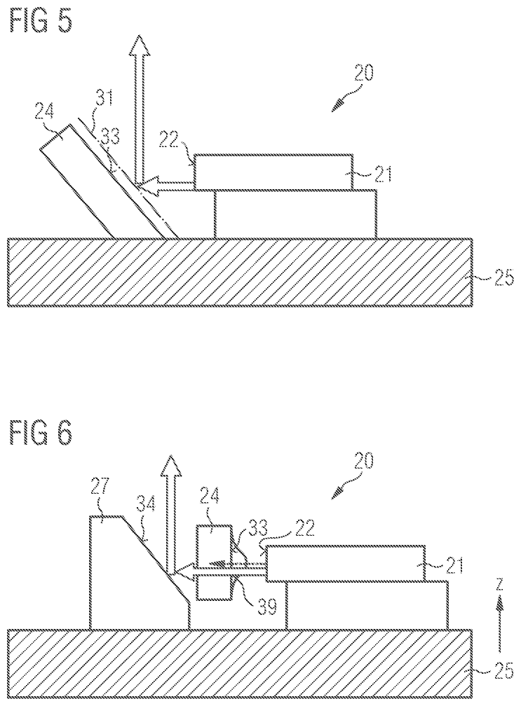

FIG. 6 shows a schematic cross-section through another exemplary embodiment of the semiconductor laser 20. Compared to the exemplary embodiment shown in FIG. 1, the photodiode 24 is arranged between the laser diode 21 and the optical element 27. The photodiode 24 is arranged on the carrier 25. Furthermore, the photodiode 24 is arranged at a distance from the laser diode 21 and at a distance from the optical element 27. Laser radiation emerging at the facet 22 impinges on the photodiode 24, with the photodiode 24 being arranged in the direction of the main emission direction of the emerging laser radiation. Thus, all or most of the laser radiation emerging from the facet 22 impinges on the photodiode 24. This enables accurate determination of the intensity of the laser radiation emerging from the laser diode 21 with an improved signal-to-noise ratio.

The photodiode 24 is at least locally transmissive to the laser radiation emitted by the laser diode 21. Thus, the emitted laser radiation passes through the photodiode 24 to the optical element 27. At the main surface 34, the laser radiation is deflected in the vertical direction z. At the main surface 34, the optical element 27 is reflective to the laser radiation. This means that the reflectivity of the main surface 34 for the incident laser radiation is, for example, at least 90% or at least 95%.

The photodiode 24 may comprise SiC or sapphire. A further optical element 39 is optionally arranged on the radiation entrance side 33 of the photodiode 24. The further optical element 39 is configured to beam-shape the laser radiation exiting the facet 22. For example, the further optical element 39 is configured to focus the laser radiation exiting the facet 22 onto the photodiode 24.

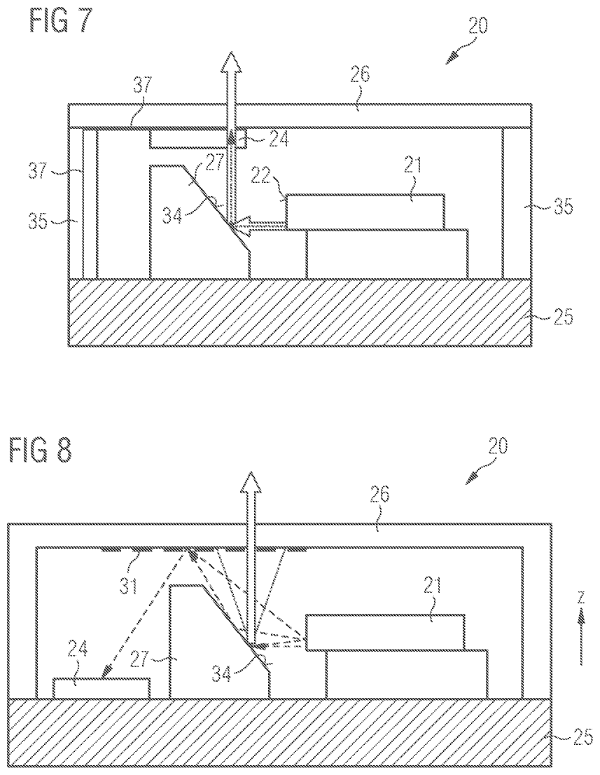

FIG. 7 shows a schematic cross-section through another exemplary embodiment of the semiconductor laser 20. Compared to the exemplary embodiment shown in FIG. 2, the photodiode 24 is attached to the cover 26 of the semiconductor laser 20. The cover 26 or a portion of the cover 26 may be a growth substrate for the photodiode 24. The growth substrate may comprise sapphire or SiC. Further, the photodiode 24 is at least locally transmissive to the laser radiation emitted by the laser diode 21. An electrical contact 37 is arranged in one of the side walls 35 and in places on the cover 26 for electrically contacting the photodiode 24. Thus, the photodiode 24 can be controlled via the carrier 25. The optical element 27 has a high reflectivity at the main surface 34 for the laser radiation emitted by the laser diode 21. For example, the reflectivity of the main surface 34 is at least 90% or at least 95% for the laser radiation emitted by the laser diode 21.

Thus, most of the laser radiation exiting the facet 22 is reflected off the main surface 34 towards the cover 26. The photodiode 24 is attached to the cover 26 in the area where a majority of the reflected laser radiation impinges on the cover 26. Thus, all or most of the emitted laser radiation impinges on the photodiode 24, which increases the accuracy of the measurement of the intensity of the emitted laser radiation. The emitted laser radiation exits the semiconductor laser 20 through the photodiode 24 and the cover 26.

FIG. 8 shows a schematic cross-section through another exemplary embodiment of the semiconductor laser 20. Compared to the exemplary embodiment shown in FIG. 7, the photodiode 24 is not attached to the cover 26, but is arranged on the carrier 25. The photodiode 24 is arranged adjacent to the optical element 27, so that the optical element 27 is arranged between the laser diode 21 and the photodiode 24. The cover 26 is partially transmissive to the laser radiation emitted by the laser diode 21. This means that part of the laser radiation reflected off the main surface 34 exits the semiconductor laser 20 through the cover 26 in the vertical direction z. Part of the laser radiation incident on the main surface 34 is scattered at the main surface 34 and reaches the photodiode 24 via total reflection at the cover 26. The main extension plane of the photodiode 24 is parallel to the main extension plane of the carrier 25. The portion of the laser radiation which exits the semiconductor laser 20 through the cover 26 is substantially larger than the portion of the laser radiation which is scattered at the main surface 34.

Optionally, a partially reflective layer 31 is arranged on the cover 26, said partially reflective layer having a very low reflectivity and a high transmissivity for the emitted laser radiation. This means that a small portion of the laser radiation is reflected at the partially reflective layer 31 and can reach the photodiode 24. The majority of the laser radiation incident on the partially reflective layer 31 exits the semiconductor laser 20 through the partially reflective layer 31 and the cover 26. This exemplary embodiment allows for a compact design of the semiconductor laser 20.

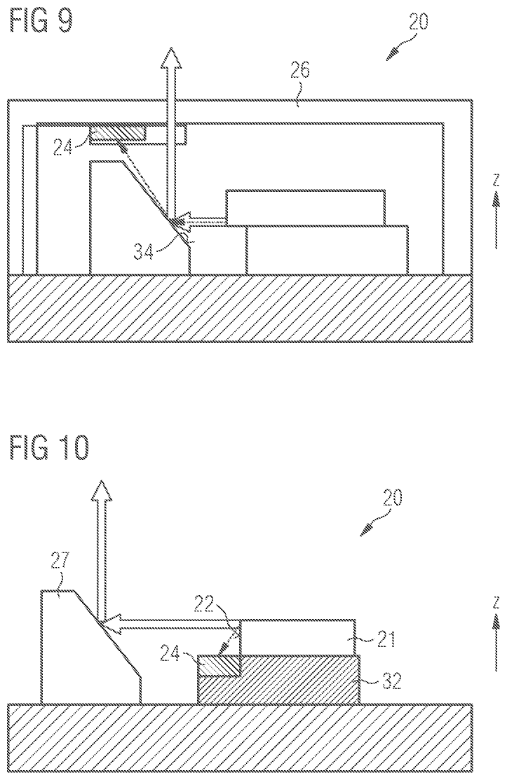

FIG. 9 shows a schematic cross-section through another exemplary embodiment of the semiconductor laser 20. Compared to the exemplary embodiment shown in FIG. 7, the photodiode 24 is not arranged along the main propagation direction of the laser radiation. Arrows indicate that the main propagation direction of the laser radiation reflected at the main surface 34 is in the vertical direction z. The reflected laser radiation exits the semiconductor laser 20 through the cover 26. The photodiode 24 is attached to the cover 26 and is located adjacent to the area where a majority of the emitted laser radiation exits the semiconductor laser 20 through the cover 26. The photodiode 24 is not necessarily transmissive to the laser radiation. A small portion of the laser radiation incident on the main surface 34 is scattered in other directions. In addition, the laser beam exhibits some divergence. Thus, part of the laser radiation reaches the photodiode 24 and is detected there.

FIG. 10 shows a schematic cross-section through another exemplary embodiment of the semiconductor laser 20. Compared to the exemplary embodiment shown in FIG. 1, the photodiode 24 is arranged in the connection carrier 32. Here, the photodiode 24 is arranged on the side of the facet 22 in the connection carrier 32. The optical element 27 has a high reflectivity for the emitted laser radiation. Laser radiation incident on the optical element 27 is deflected in the vertical direction z. The photodiode 24 is configured to detect scattered light of the laser radiation emerging from the facet 22. Thus, the laser radiation emerging from the laser diode 21 can be directly monitored by the photodiode 24.

FIG. 11A shows a top view of another exemplary embodiment of the semiconductor laser 20. The semiconductor laser 20 comprises three laser diodes 21. The laser diodes 21 are arranged on the connection carrier 32, which is arranged on the carrier 25. The main emission directions of the laser diodes 21 are parallel to each other. Furthermore, the optical element 27 is arranged at a distance from the laser diodes 21 on the carrier 25. The optical element 27 is arranged such that the laser radiation emitted from each of the laser diodes 21 at the facet 22 is incident on the main surface 34. Further, the semiconductor laser 20 comprises two photodiodes 24. Each of the photodiodes 24 is arranged between two respective laser diodes 21 in the lateral direction x. The photodiodes 24 may be arranged on the connection carrier 32, on the carrier 25 or in the carrier 25.

An optical filter 30 is arranged on one of the two photodiodes 24. No optical filter 30 is arranged on the other photodiode 24. The optical filter 30 is transmissive to the laser radiation emitted by the laser diodes 21. Electromagnetic radiation in other wavelength ranges is largely absorbed by the optical filter 30. By comparing the radiation detected by the two photodiodes 24, the proportion of background radiation and scattered light can be determined. Thus, the signal-to-noise ratio of the detected laser radiation can be improved.

FIG. 11B shows a schematic cross-section through the exemplary embodiment of the semiconductor laser 20 shown in FIG. 11A. A partially reflective layer 31 is arranged on the side of the cover 26 facing the carrier 25. A small portion of the laser radiation emitted from the laser diodes 21 is reflected at the partially reflective layer 31. Thus, part of the laser radiation reaches the photodiodes 24. The cover 26 is at least in places transmissive to the radiation emitted by the laser diodes 21. The radiation entrance side 33 of the photodiodes 24 is arranged on the side of the photodiodes 24 facing away from the carrier 25.

FIG. 12 shows a top view of an exemplary embodiment of a photodiode 24. The photodiode 24 is the photodiode 24 of the exemplary embodiment shown in FIGS. 11A and 11B, on which the optical filter 30 is arranged. The filter 30 has three different filter regions 38. In addition, the photodiode 24 has three segments. One filter region 38 is arranged above each of the segments. One of the laser diodes 21 is associated with each of the filter regions 38. The filter regions 38 are transmissive to the laser radiation emitted by the associated laser diode 21 and impermeable to other wavelength ranges. For example, one of the filter regions 38 is transmissive to red light, one of the filter regions 38 is transmissive to blue light, and one of the filter regions 38 is transmissive to green light. The photodiode 24 further comprises two electrical contacts 37 for electrically contacting the photodiode 24.

As an alternative to the exemplary embodiment shown in FIG. 12, the semiconductor laser 20 of the exemplary embodiment shown in FIGS. 11A and 11B may comprise a total of four photodiodes 24. In this case, an optical filter 30 is disposed on each of three of the photodiodes 24. Each of the optical filters 30 is associated with one of the laser diodes 21 as described above. No optical filter 30 is arranged on the fourth photodiode 24.

FIG. 13A shows a schematic cross-section through another exemplary embodiment of the semiconductor laser 20. Compared to the exemplary embodiment shown in FIG. 5, the photodiode 24 has an uneven or curved surface. Here, the curved surface faces the facet 22 of the laser diode 21. The partially transparent layer 31 arranged on the surface of the photodiode 24 also has a curved shape. Overall, the surface of the photodiode 24 has a concave shape. This means that the surface of the photodiode 24 is curved inward. Thus, the surface of the photodiode 24 with the partially transparent layer 31 serves for beam deflection and beam shaping of the laser radiation emitted by the laser diode 21. The photodiode 24 has an active region 40 which is configured to detect electromagnetic radiation during operation of the photodiode 24. The active region 40 extends parallel to the curved surface of the photodiode 24.

FIG. 13B shows a top view of a portion of the photodiode 24 shown in FIG. 13A. The cross-section shown in FIG. 13A is along the dashed line. The photodiode 24 is arranged on the carrier 25. In the top view, the curvature of the surface is shown to be circular.

FIG. 13C shows a schematic cross-section through another exemplary embodiment of the semiconductor laser 20. Compared to the exemplary embodiment shown in FIG. 13A, the active region 40 of the photodiode 24 extends parallel to the main extension plane of the photodiode 24.

This patent application claims the priority of German patent application 102018128751.8, the disclosure content of which is hereby incorporated by reference.

The invention is not limited to the exemplary embodiments by the description based on the same. Rather, the invention encompasses any new feature as well as any combination of features, which in particular includes any combination of features in the patent claims, even if this feature or combination itself is not explicitly stated in the patent claims or exemplary embodiments.

### LIST OF REFERENCE SIGNS

20: semiconductor laser
21: laser diode
22: facet
23: radiation exit region
24: photodiode
25: carrier
26: cover
27: optical element
28: housing
29: recess
30: filter
31: partially reflective layer
32: connection carrier
33: radiation entrance side
34: main surface
35: side walls
36: cavity
37: electrical contact
38: filter region
39: further optical element
40: active region
x: lateral direction
z: vertical direction

1. A semiconductor laser comprising:
an edge-emitting laser diode, which has an active zone for generating laser radiation and a facet having a radiation exit region, and
at least one photodiode,
wherein
the facet is arranged on a main emission side of the laser diode,
the photodiode is arranged in such a way that at least part of the laser radiation exiting at the facet reaches the photodiode, photodiode, and
the laser diode and the photodiode are not connected to each other in a non-destructively detachable manner, and
a non-destructively detachable connection is formed with a joining partner.

2. The semiconductor laser according to claim 1, in which the photodiode and the laser diode are arranged on a common carrier.

3. The semiconductor laser according to claim 1, in which the photodiode is attached to a cover of the semiconductor laser.

4. The semiconductor laser according to claim 1, in which an optical element is arranged between the laser diode and the photodiode, the optical element being configured to direct part of the laser radiation emitted by the laser diode towards the photodiode.

5. The semiconductor laser according to claim 4, in which the optical element is arranged on a carrier for the photodiode and the laser diode.

6. The semiconductor laser according to claim 4, in which the optical element is partially transmissive to the laser radiation emitted by the laser diode and is partially reflective to the laser radiation emitted by the laser diode.

7. The semiconductor laser according to claim 4, in which the optical element is configured to change the main propagation direction of at least part of the laser radiation emitted by the laser diode.

8. The semiconductor laser according to claim 1, in which the photodiode is at least locally transmissive to the laser radiation emitted by the laser diode.

9. The semiconductor laser according to claim 1, which has on a radiation exit side a cover which is partially transmissive to the laser radiation emitted by the laser diode and partially reflective to the laser radiation emitted by the laser diode.

10. The semiconductor laser according to claim 1, in which the laser diode and the photodiode are arranged in a common housing.

11. The semiconductor laser according to claim 1, in which the photodiode is a component of a carrier for the laser diode.

12. The semiconductor laser according to claim 1, in which a carrier for the laser diode comprises a recess in which the photodiode is arranged.

13. The semiconductor laser according to claim 1, in which the main extension plane of the photodiode is transverse or perpendicular to the main extension plane of the facet.

14. The semiconductor laser according to claim 1, in which the main extension plane of the photodiode is parallel to the main extension plane of the facet.

15. The semiconductor laser according to claim 1, in which an optical filter is arranged on the photodiode at least in places.

16. The semiconductor laser according to claim 1, in which a partially reflective layer is arranged on the photodiode, said partially reflective layer being configured to direct part of the laser radiation emitted by the laser diode towards the photodiode.

17. The semiconductor laser according to claim 1, in which a surface of the photodiode is uneven.
